(19) United States
(12) Patent Application Publication
(10) Pub. No.: US 2006/0197182 A1
(43) Pub. Date: Sep. 7, 2006

(54) High frequency integrated circuits

(76) Inventors: Yinon Degani, Highland Park, NJ (US); Charley Chunlei Gao, San Diego, CA (US); Huainan Ma, Plano, TX (US); King Lien Tai, Berkeley Heights, NJ (US)

Correspondence Address: Law Firm of Peter V.D. Wilde, 301 East Landing, Williamsburg, VA, 23185, US

(21) Appl. No.: 11/411,307

(22) Filed: Apr. 26, 2006

Related U.S. Application Data
(63) Continuation of application No. 10/277,239, filed on Oct. 21, 2002.

(51) Int. Cl. H01L 29/00

(52) U.S. Cl. 257/531; 257/532

(57) ABSTRACT

The specification describes a silicon-on-silicon interconnection arrangement to implement high performance RF impedance matching using off-chip passive components. The RF sections of the system are dis-integrated into separate RF functional chips, and the functional chips are flip-chip mounted on a high resistivity silicon intermediate interconnect substrate (SIIS). The passive devices for the impedance matching networks are built into the high resistivity SIIS using thin-film technology.

### RELATED APPLICATIONS

This application is a continuation of application Ser. No. 10/277,239, filed Oct. 21, 2002.

### FIELD OF THE INVENTION

This invention relates to high frequency RF multi-chip modules (MCMs) with improved impedance matching networks.

### BACKGROUND OF THE INVENTION

(The technical material contained in this section may or may not be prior art unless specifically identified as such.)

For several decades, integrated circuit technology has evolved with ever increasing levels of integration. From both size and cost standpoints, greater device density and smaller lithographic line rules has been the most compelling trend in the technology. Integration allows IC chips to be made smaller, and also allows more and more components of the system to be integrated on a single chip. Electronic systems that were manufactured just a few years ago using multi-chip modules are now being implemented in large single chips. An example that is relevant to the invention to be described below is an RF system in which the primary functional blocks are integrated on a single chip to produce a “radio on a chip”.

In RF systems, the quality of RF inputs and outputs from one RF section to another is usually limited by parasitics and the mismatch of the impedance of the lines that carry the signal between sections or between components. This impedance mismatch causes reflections of signals that translate to distorted signals and power loss. Consequently, impedance matching is required in order to optimize the power delivered to the load from the source. Impedance matching is accomplished by inserting matching networks into a circuit between the source and the load. A simple example is matching unequal source and load resistances with an inductance (L)-capacitance(C) circuit. In a transistor amplifier, the impedance matching is typically between a resistive source and a resistive load using a series-inductance shunt-capacitance network to optimize the transducer power gain of the transistor amplifier.

As the frequency of the network changes, the design of the matching network changes, and very high frequency circuits require precise matching networks with high performance components.

Impedance mismatch was addressed early in the development of RF IC system technology by hybrid ICs, where the impedance matching elements (L,C) were assembled as discrete devices or subsystems in close proximity to the I/Os of the IC chips, thus matching the I/O impedance to the signal line impedance. However, as integration progressed during the 80's, matching elements were integrated in the silicon chips. This trend continued until now, with state of the art RF devices, many chips have been integrated into a few chips, or even a single system chip. So the technology has advanced to the point where all of the active and passive components for a complete RF system may be integrated on a single IC chip. See for example,
http://www.semiconductor.com/reports/search_detail.asp?device=5819&report=1620
   This reference describes a complete functional radio on a single IC chip for the 5 GHz wireless market. See also
www.siliconwave.com/pdf/61_{—}0002_R00C_SiW1100_PS.pdf
   which describes Silicon Wave's Sentinel™ SiW1100 highly integrated, ultra low-power downstream cable tuner IC designed for broadband cable telephony applications. This device integrates all performance-critical RF elements onto a single, low-power device. The integrated frequency synthesizers include VCOs and require no external resonator elements.

However, there remains a debate on the most efficient high frequency RF circuit design. The debate involves, inter alia, whether to place the passive elements “on-chip” or “off-chip”. See:
http://www.okisemi.com/public/docs/PR-aAsPowerMMIC.html.
   Resolution of that debate, for a given circuit application, depends on how efficiently the on-chip integration can be implemented, or how the off-chip option is implemented.

Other advances in IC integration and packaging allow very efficient and compact overall system design. For example, use of silicon-on-silicon in premium interconnection assemblies is growing rapidly due in part to the nearly optimum thermo-mechanical design made possible by the match between the Coefficient of Thermal Expansion (CTE) of the silicon chip and the silicon interconnection substrate. In state of the art silicon-on-silicon packages that provide ultra-high density, silicon chips may be flip-chip attached to an intermediate silicon wafer substrate, and the silicon wafer substrate is in turn mounted on a motherboard. The use of silicon substrate wafers allows for sophisticated interconnect arrangements between the active IC chip(s) and the system interconnection board, typically an epoxy glass printed wiring board.

### SUMMARY OF THE INVENTION

We have designed a silicon-on-silicon interconnection arrangement to implement high performance RF impedance matching that overcomes many of the deficiencies of prior art circuits with off-chip passive components. In the package of the invention the RF sections of the system are dis-integrated into separate RF functional chips and the functional chips are flip-chip mounted on a high resistivity silicon intermediate interconnect substrate (SIIS). The passive devices for the impedance matching networks are built into the high resistivity SIIS using thin-film technology. In the typical prior art implementation in which the passive networks are off-chip, the passive devices are discrete elements mounted on an epoxy/glass printed wiring board. The assembly of the invention offers the advantage of allowing the silicon flip-chips to be surface mounted directly to the SIIS intermediate board level without significant CTE mismatch. It also allows the impedance matching elements to be efficiently formed on a high resistivity substrate using well-developed silicon IC technology.

### BRIEF DESCRIPTION OF THE DRAWING

FIG. 1 is a functional block diagram for a typical RF cellular system;

FIG. 2 shows in schematic form an integrated IC chip for implementing a system similar to that of FIG. 1, with impedance matching networks fully integrated with the RF functional blocks;

FIG. 3 shows an example of a simple impedance matching network for a transistor amplifier;

FIG. 4 is a schematic view of a typical prior art RF integrated circuit assembly with impedance matching components “off-chip”.

FIG. 5 is a schematic view of an RF integrated circuit assembly according to the preferred embodiment of the invention in which the impedance matching elements are formed in a SIIS;

FIG. 6 is a view similar to that of FIG. 4 showing an alternative embodiment of the invention; and

FIGS. 7-14 are schematic representations of steps useful for forming typical impedance matching components on the SIIS.

### DETAILED DESCRIPTION

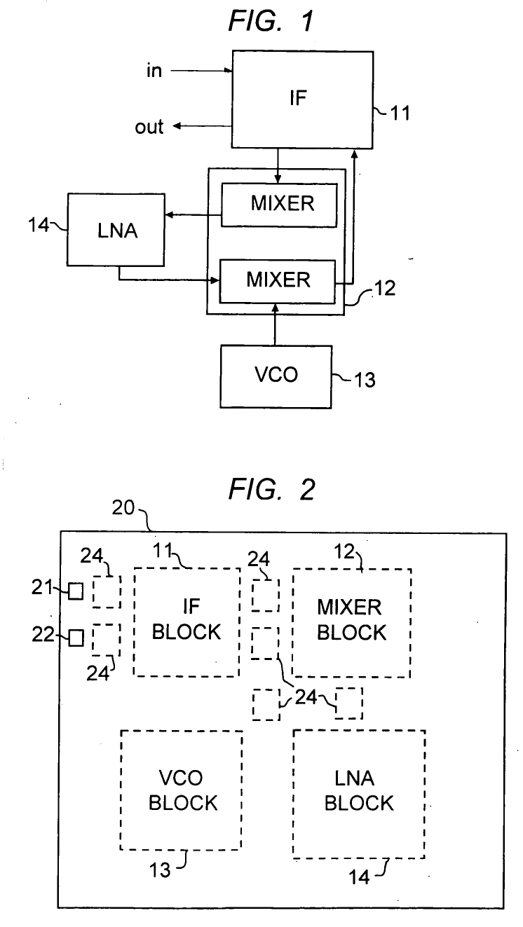

A schematic circuit diagram showing the interconnections between typical functional subcircuits of a high frequency RF cellular device is shown in FIG. 1. The input/output is shown with IF stage 11. The IF functional subcircuit, the low noise amplifier (LNA) subcircuit 14, and the voltage controlled oscillator subcircuit 13, with mixers in the mixer subcircuit block 12, are shown in a typical arrangement. Two, three, or all four of these functional blocks may be integrated in one IC chip. The fully integrated version is represented in FIG. 2.

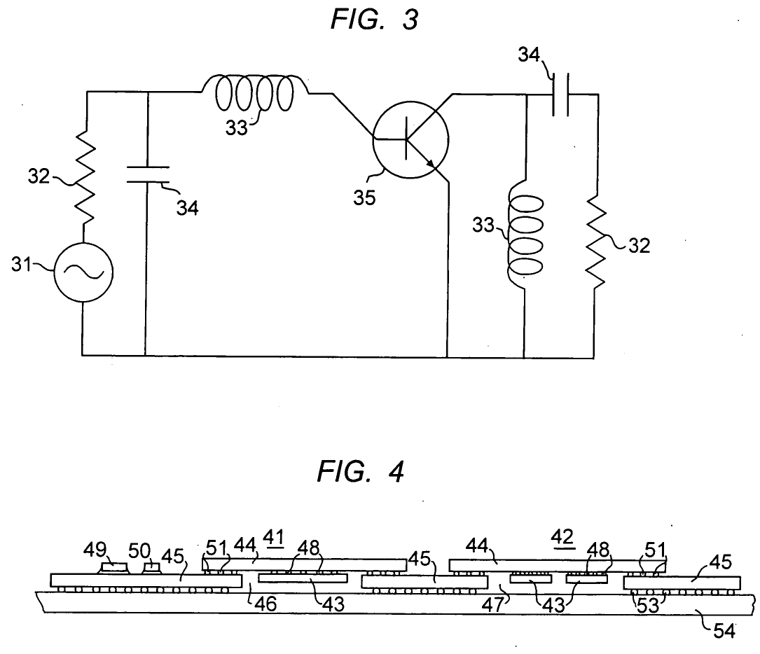

Referring to FIG. 2, a fully integrated implementation of the functional block diagram of FIG. 1 is shown. It comprises IF BLOCK 11, MIXER BLOCK 12, (Voltage Controlled Oscillator) VCO BLOCK 13, and (Low Noise Amplifier) LNA BLOCK 14. These RF functions can be implemented effectively in silicon and therefore can be fully integrated together on one chip. The power amplifiers are frequently formed in GaAs for better noise performance, so this functional block typically is not fully integrated, and is not shown. I/O contact pads are shown at 21 and 22. These are illustrative of, typically, many such pads only two of which are shown. Impedance matching networks are indicated schematically at 24. These matching networks are L/C circuits usually comprising capacitors, inductors and resistors. They are interconnected in the runners routing interconnections between the I/O pads and IF block, and between the functional blocks. The specifics of the impedance matching circuits form no part of the invention and are not treated in detail here. However, for illustration only, a simple impedance matching network for a transistor amplifier is shown in FIG. 3. The transistor 35 is impedance matched between signal 31 and load 32 by inductor elements 33, capacitor elements 34 and resistors 32. This figure is included to illustrate the typical impedance matching elements.

In the nearly uninterrupted quest for ever-increased integration that has characterized IC technology since the beginning, rare situations occur where the next step in integration actually may cause a step backward in performance. A good example is the integrated system of FIG. 2. Here the size of the system has been dramatically reduced by placing all circuit functions, including the impedance matching elements, on one IC chip. However, at very high frequencies, the impedance matching elements do not perform well because they are situated on a relatively conductive substrate. The substrate in this case must be relatively conductive, i.e. semiconductive, to support the active elements. This paradox has been recognized, and it has been suggested that impedance matching networks be located off-chip. One approach to this, using silicon-on silicon for efficient interconnection in a multi-chip module (MCM) IC system package, is shown in FIG. 4.

Referring to FIG. 4 two silicon-on-silicon multi-chip-modules (MCMs) are shown generally at 41 and 42. The dimensions of the interconnected elements are not necessarily to scale. The MCMs comprise silicon IC chips 43 flip-chip bonded to silicon interconnection substrate 44. The side designated 41 illustrates or a single silicon chip flip-chip bonded to a SIIS. The side designated 42 illustrates multiple IC chips attached to the SIIS. This single figure represents a case (41) where a single IC chip integrates all of the RF functions as shown in FIG. 2, or where the RF functions are dis-integrated into several IC chips (42) each of which performs one or more of the RF functions. The choice of the level of integration is wide, and the invention described herein is intended to encompass any such choice from full integration (FIG. 2), to partial integration, to separate chips for each RF block (FIG. 5). The silicon chips may be bonded with either edge arrayed or area arrayed solder bumps to the SIIS. In this description the term solder bump is used for convenience to generically describe solder interconnections in any suitable configuration or form. The solder interconnections between the silicon chips and the SIIS are shown at 48.

In a conventional package, the silicon-on-silicon MCM is bonded to a laminated epoxy PWB. Printed circuits can be provided on the underside of the silicon substrate and the silicon substrate surface mounted onto the PWB. A typical arrangement is to mount the silicon-on-silicon MCM in a flip-chip mode onto a PWB as shown in FIG. 4. The PWB is shown at 45 and has apertures 46 and 47 (optional) to allow the silicon chips 43 to extend beneath the surface of the board, thereby decreasing the vertical profile of the package. The silicon-on-silicon MCMs 41 and 42 are solder bonded to the PWB with solder bumps 51. This interconnection arrangement is described and claimed in U.S. Pat. No. 5,646,828, issued Jul. 8, 1997. The RF impedance matching components, capacitors, inductors, resistors, are shown 49 and 50 in FIG. 4, surface mounted on the PWB. The PWB 45 typically consists of epoxy/glass, commonly referred to in the art as FR-4. For high density interconnect packages, the PWB 45 may be mounted with solder bumps 53 on another laminated board, shown in FIG. 4 at 54, which is typically the final level of interconnection. PWB 54 also comprises FR-4, or one of several alternative materials known in the art. Efforts can be made to select laminated board materials that have matched CTE values, i.e. values close to 16 ppm/° C., to minimize differential thermal expansion problems between the PWBs and the silicon substrates.

According to the invention, the impedance matching networks are formed as thin film elements on the silicon interconnection substrate, referred to earlier as SIIS. The SIIS is preferably made of high resistivity silicon. Since there are no active devices in the SIIS in this arrangement, the resistivity can be made near intrinsic. This allows the capacitor and inductor elements of the impedance matching networks to be made reliably and reproduceably, with quality factors essentially matching elements formed on insulating substrates, e.g. ceramics. Thus an effective marriage results, between silicon-on-silicon interconnection technology, for high performance packaging, and meeting the need for improved RF impedance matching.

An embodiment showing this combination is shown in FIG. 5, where each of the RF functions of FIG. 1 is implemented in individual IC chips 62, 63, 64, and 65, and these IC chips are flip-chip attached to SIIS 61. Bond pads, represented by the two shown at 66, are provided for attachment of the SIIS to a motherboard. The impedance matching networks, represented by 67, are formed directly on the SIIS. The SIIS 61 may then be flip-chip attached to a PWB as in the embodiment of FIG. 4.

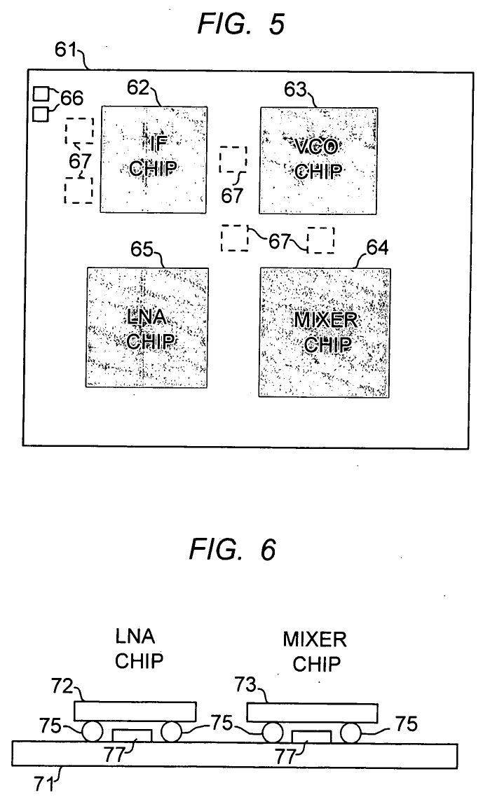

In FIG. 5, the impedance matching elements are situated between the IC chips as shown. In some cases where space is at a premium, the impedance matching network, or elements of the network, may be situated under the IC chips. This embodiment is shown in FIG. 6, where two of the RF functional IC chips 72 and 73 are shown attached to SIIS 71 by solder bumps 75, and impedance matching elements 77 are shown situated in the standoff between the IC chips and the SIIS.

Details of suitable capacitor, resistor and inductor elements that may be formed by thin film techniques are known in the art. A common approach to forming a capacitor on silicon is to replicate an MOS gate structure. Using a high resistivity SIIS this would involve depositing a polysilicon or amorphous silicon layer, growing or depositing an SiO₂ layer, and depositing the polysilicon counterelectrode. Silicon resistors may be made using one of the polysilicon layers.

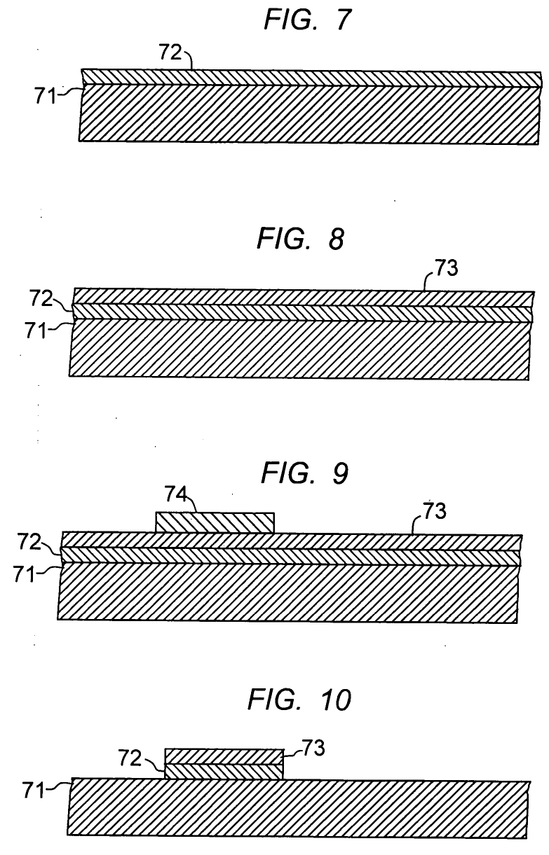

Other approaches may be used for forming the L/C elements. A preferred method is to use tantalum technology. An example of this approach will be described in conjunction with FIGS. 7-18. It should be understood that these methods are mentioned as examples only, and a variety of other choices are available to those skilled in the art for implementing the thin film impedance matching networks on the SIIS according to the invention.

Referring to FIG. 7, a cutaway portion 71 of an SIIS is shown. The SIIS may have a layer of SiO₂ grown or deposited on the surface. Layer 72 of tantalum is deposited on the surface of the SIIS. The layer 72 of tantalum may be deposited by sputtering or other appropriate deposition technique. Sputtering from a DC magnetron source, at a pressure of 5-20 mtorr flowing argon, and a power density of 0,1-2 W/cm², are suitable sputtering conditions. The deposition rate at the high power level is approximately 2250 Angstroms/min. An appropriate thickness range for this layer is 1 to 5 μm.

Layer 73 of tantalum nitride is then deposited over layer 72 as shown in FIG. 8. This layer is optional but does improve adhesion of layers subsequently deposited on the structure. A suitable thickness range for layer 73 is 1 to 2 μm. Layer 73 can be formed in the manner described for layer 72 with the added step of introducing nitrogen in the flowing argon at a concentration in the range 10-30%.

The materials designated for layer 72 and optional layer 73 represent but one embodiment. Other capacitor materials may also be suitable, e.g. Ti, Zr, or Al. These materials can be anodized readily to form the capacitor dielectric, as will be described below for the choice illustrated, i.e. Ta.

With reference to FIG. 9, layer 72, or layers 72 and 73, are then lithographically patterned using a photomask 74 to define the first electrode of the capacitor. The exposed portions of layer 72, or layers 72 and 73, are removed using a 1:2:4 etch of HF, HNO₃ and water, to give the structure shown in FIG. 10.

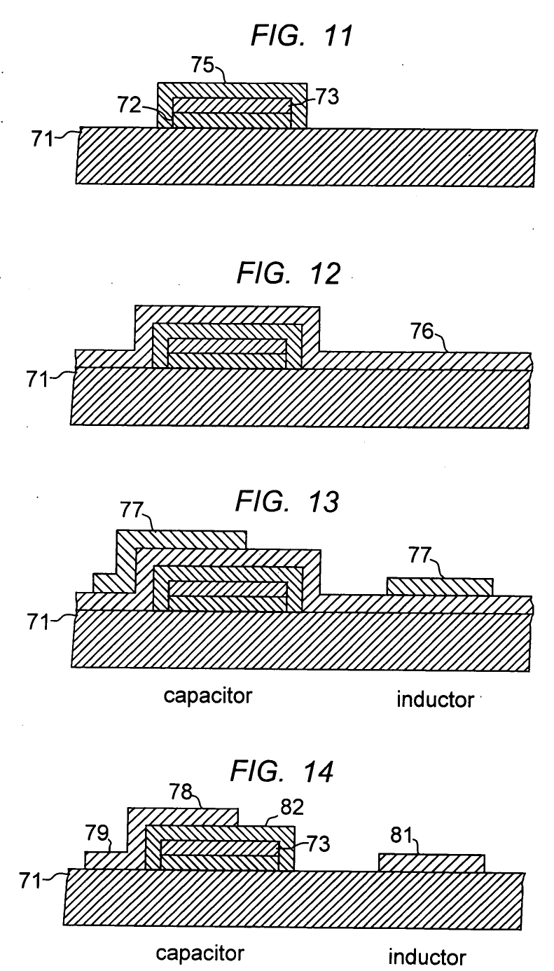

The next step, represented by FIG. 11, is to form the capacitor dielectric 75 by anodizing the first electrode of the capacitor. The SIIS may be placed in an electrolyte of 0.1 wt. % aqueous citric acid, and anodized using a platinum cathode and a voltage that is ramped at constant current for about 10 minutes to reach 100 V, and held for approximately an hour. The resulting tantalum oxide film is approximately 1800 Angstroms. Other oxide forming techniques, such as plasma oxidation, can be used. The objective is to form a uniform film in the thickness range 0.05 to 0.5 μm.

With the capacitor dielectric formed, the second electrode is formed by blanket depositing a metal layer 76 over the structure as shown in FIG. 12. In the preferred embodiment this layer is aluminum, although other suitable conductor materials can be substituted. Aluminum may be DC magnetron sputtered using conditions similar to those given for tantalum sputtering except that higher power levels, i.e. a power density as high as 6 W/cm² can be used, which deposits the film at a rate of 1 μm/min. A suitable thickness range for layer 16 is 0.3 to 1 μm.

Referring to FIG. 13, layer 76 is patterned photolithographically using photomask 77. For illustration, this step involves the formation of two components, a capacitor as already described, and an inductor to be formed at the site indicated. Etchants for aluminum are well known. A suitable etchant is PAE available from General Chemical Co., Parsippany, N.J.

After patterning aluminum layer 76 and removing mask 77 the structure appears as in FIG. 14. The counterelectrode for the capacitor is shown at 78 and a conductive strip, that will become the primary element of the inductor, is shown at 81. The inductance of the inductor is determined by the dimensions of the spiral strip 81.

As will occur to those skilled in the art, other components can also be formed using a processing sequence compatible with that described here. For example, the element designated 81 for the inductor in this sequence, can be polysilicon, with the objective of forming a resistor. The polysilicon can be deposited e.g. by evaporation or CVD, and patterned lithographically. The same steps as described below for the inductor can be used to complete the resistor. The resistance value is determined by choice of the length and cross section of the strip 81, and/or by modifying the conductivity of the polysilicon by appropriate dopants either during the deposition or with a post deposition implant. It is also convenient and fully compatible with the process as described to form resistors of TaN.

The electrode 78 has extended portion 79 that extends beyond the capacitor edge laterally along the surface of the SIIS 71 as shown in FIG. 14 to facilitate interconnection with a printed circuit on the SIIS, or layer 78, 79 may be part of the printed interconnection circuit. The capacitance of the capacitor is primarily determined by the design, i.e. area, of the capacitor plates and the thickness of the capacitor dielectric, but can be further trimmed photolithographically by adjusting the photomask laterally to expose more, or less, of the counterelectrode 78 to be etched away.

The use of photolithography in the steps described is the preferred technique. However, some dimensions may be relatively large by lithography standards. Accordingly, some or all the elements may be formed by other techniques, such as lift-off, or even shadow masking.

The various elements in the figures are not drawn to scale. For example, the aspect ratio, i.e. width to thickness, is typically much larger than that shown.

It will be evident to those skilled in the art that the geometric configuration of the capacitor plates may have a variety of forms. Typically the capacitor geometry in plan view is square or rectangular. The inductor may also have a variety of shapes, e.g. spiral.

The capacitor dielectric in the above description is an oxide formed by anodizing the first capacitor electrode according to well-known tantalum capacitor technology. However, other dielectrics, including nitrides or oxynitrides may also be used. Also the dielectric may be grown by other techniques, e.g. plasma techniques, or it may be deposited by a suitable deposition technique, e.g. CVD.

In the foregoing description, the RF functional integrated circuit chips are attached to a silicon substrate. Optionally, a PWB substrate, a ceramic substrate, or the like, may be used.

In the usual case the four integrated circuit chips shown in FIG. 5 will be silicon IC chips. It may occur to those skilled in the art that since the functional blocks of the overall RF system are dis-integrated according to one aspect of the invention, that one or more GaAs chips may easily be interconnected on the SIIS. Thus the entire RF system, including for example a GaAs power amplifier chip, can be mounted on a single SIIS.

For the purpose of defining the invention, the term high frequency RF integrated circuit chip as used herein is intended to mean an integrated circuit for processing an RF signal with a frequency in excess of 3 GHz.

Various additional modifications of this invention will occur to those skilled in the art. All deviations from the specific teachings of this specification that basically rely on the principles and their equivalents through which the art has been advanced are properly considered within the scope of the invention as described and claimed.

We claim:

1. An RF integrated circuit device comprising:
a. a silicon substrate, the silicon substrate having intrinsic resistivity,
b. a first high frequency RF integrated circuit chip mounted on the silicon substrate;
c. a second high frequency RF integrated circuit chip mounted on the silicon substrate,
d. a thin film capacitor formed on the silicon substrate;
e. a thin film inductor formed on the silicon substrate;
f. interconnection means interconnecting the capacitor and inductor to form an LC circuit;
g. interconnection means electrically connecting the LC circuit between the first high frequency RF integrated circuit and the second high frequency RF integrated circuit.

2. The RF integrated circuit device of claim 1 additionally including a printed wiring board (PWB) and means for attaching the silicon substrate to the PWB.

3. The RF integrated circuit device of claim 1 wherein the first and second high frequency RF integrated circuit chips are silicon chips.

4. The RF integrated circuit device of claim 1 additionally including a GaAs high frequency RF integrated circuit chip mounted on the silicon substrate.

5. A high frequency RF integrated circuit device comprising:
a. a silicon substrate, the silicon substrate having intrinsic resistivity,
b. a first high frequency RF integrated circuit chip mounted on the silicon substrate, the first high frequency RF integrated circuit chip comprising an IF circuit block;
c. a second high frequency RF integrated circuit chip mounted on the silicon substrate, the second high frequency RF integrated circuit chip comprising a mixer circuit block;
d. a third high frequency RF integrated circuit chip mounted on the silicon substrate, the third high frequency RF integrated circuit chip comprising a low noise amplifier circuit block;
e. a fourth high frequency RF integrated circuit chip mounted on the silicon substrate, the fourth high frequency RF integrated circuit chip comprising a voltage controlled oscillator circuit block;
f. a plurality of thin film capacitors formed on the silicon substrate;
g. a plurality of thin film inductors formed on the silicon substrate;
h. first interconnection means electrically interconnecting the capacitors and inductors to form a plurality of LC circuits;
j. interconnection means electrically connecting the LC circuits between selected high frequency RF integrated circuit chips.

6. The high frequency RF integrated circuit device of claim 5 additionally including a printed wiring board (PWB) and means for attaching the silicon substrate to the PWB.

7. The high frequency RF integrated circuit device of claim 6 additionally including a GaAs high frequency RF integrated circuit chip mounted on the silicon substrate.
